(19) United States
(12) Patent Application Publication
(10) Pub. No.: US 2023/0289498 A1
(43) Pub. Date: Sep. 14, 2023

(54) MACHINE LEARNING SYSTEM FOR PARAMETERIZING BUILDING INFORMATION FROM BUILDING IMAGES

(71) Applicants: SRI International, Menlo Park, CA (US); OBAYASHI CORPORATION, Tokyo (JP); Hypar Inc., Culver City, CA (US)

(72) Inventors: Anirban Roy, San Francisco, CA (US); Jihua Huang, Sunnyvale, CA (US); Sujeong Kim, Hyattsville, MD (US); Min Yin, San Jose, CA (US); Chih-hung Yeh, Alameda, CA (US); Takuma Nakabayshi, Foster City, CA (US); Yoshito Tsuji, Singapore (SG); Ian Keough, Culver City, CA (US); Matthew Campbell, Cambridge, MA (US)

(21) Appl. No.: 17/654,737

(22) Filed: Mar. 14, 2022

(51) Int. Cl. G06F 30/27; G06T 3/00; G06V 10/764; G06V 10/774; G06F 30/13

(52) U.S. Cl. CPC G06F 30/27; G06T 3/00; G06V 10/764; G06V 10/774; G06F 30/13

(57) ABSTRACT

In general, the disclosure describes techniques for parameterizing building information using images. In an example, a method includes receiving an image of a building; applying, by a machine learning system, a machine learning model to the received image of a building to generate, for a new building, new building parameters to be input to a building information modeling (BIM) data generation system, wherein the machine learning model is trained using images of buildings and corresponding building parameters for the buildings; and outputting, by the machine learning system, the new building parameters for the new building.

### TECHNICAL FIELD

This disclosure is related to machine learning systems, and more specifically to machine learning systems for building design.

### BACKGROUND

Machine Learning (ML) typically involves training a machine learning model with training data to produce a trained model able to generalize properties of data based on similar patterns with the training data. Training the model often involves learning model parameters by optimizing an objective function, thus optimizing a likelihood of observing the training data given the model. For some applications, in addition to minimizing the objective function, a trained model may need to satisfy additional properties that are important for the domain.

### SUMMARY

In general, the disclosure describes techniques for parameterizing building information using images. For example, a machine learning system may train a machine learning model with training data that includes images of buildings and corresponding known descriptive data for the buildings for one or more building parameters, such as building dimensions, number of floors, window locations and dimensions, floor height, interior layouts, and others. In inference mode, the machine learning system may apply the trained model to an image of a building to predict values of the building parameters of the building. These predicted values of the building parameters may be output for use in designing a new building and may be input to a building information modeling (BIM) data generation system for generating BIM data for the new building. The BIM data generation system may use the generated building parameters to, for instance, replicate the exterior façade or the architectural style of the building in a three-dimensional (3D) architectural model.

The techniques may provide one or more technical advantages that realize at least one practical application. Current architectural practice is for architects to manually specify the building parameters for generating the desired building or to manually lay out each architectural element by hand in a design program, such as a computer-aided design (CAD) program. This can be time consuming and may require expertise with the program. The techniques may simplify building design by enabling an architect to quickly generate a 3D architectural model having building parameters that are similar to an existing building for which the architect has an image. The architect may then modify the building parameters, predicted by the machine learning model for the existing building, to more quickly arrive at a new candidate building that is suited for the requirements of the architectural project or other intent of the architect. Once a new candidate building is arrived at using the generated building parameters, a BIM data generation system can process the building parameters to output BIM data for the new candidate building. Such requirements may conform to and be helpful for meeting structural engineering, environmental planning, and legal planning requirements, for example.

In an example, a machine learning system for predicting building parameters for an image of a building comprises: an input device configured to receive an input comprising an image of a building; processing circuitry and memory for executing a machine learning system, wherein the machine learning system is configured to apply a machine learning model, trained using images of buildings and corresponding building parameters for the buildings, to the received image of the building to generate, for a new building, new building parameters to be input to a BIM data generation system; and an output device configured to output the new building parameters for the new building.

In an example, a method includes receiving an image of a building; applying, by a machine learning system, a machine learning model to the received image of a building to generate, for a new building, new building parameters to be input to a BIM data generation system, wherein the machine learning model is trained using images of buildings and corresponding building parameters for the buildings; and outputting, by the machine learning system, the new building parameters for the new building.

In an example, a non-transitory computer-readable medium comprises machine readable instructions for causing processing circuitry to perform operations comprising: receiving an image of a building; applying a machine learning model to the received image of a building to generate, for a new building, new building parameters to be input to a BIM data generation system, wherein the machine learning model is trained using images of buildings and corresponding building parameters for the buildings; and outputting the new building parameters for the new building.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1 is a block diagram illustrating example system in accordance with the techniques of the disclosure.

FIG. 2 is an example of a computing system, according to techniques of this disclosure.

FIG. 3 is a flowchart illustrating an example mode of operation for a machine learning system, according to techniques described in this disclosure.

Like reference characters refer to like elements throughout the figures and description.

### DETAILED DESCRIPTION

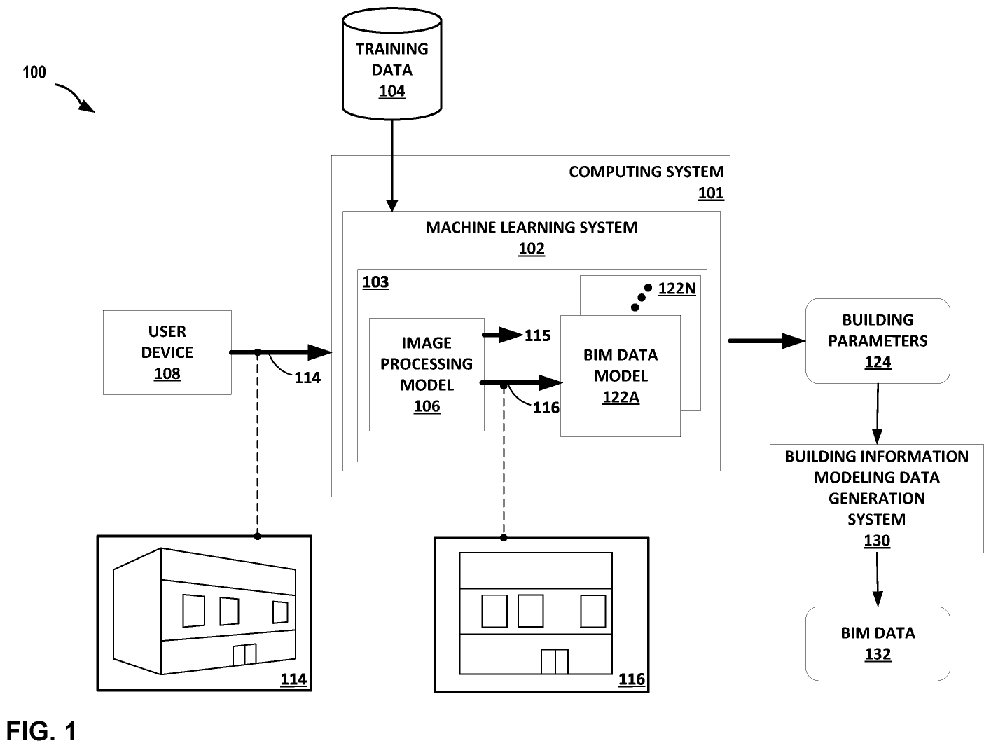

FIG. 1 is a block diagram illustrating example system 100 in accordance with the techniques of the disclosure. As shown, system 100 includes user device 108, computing system 101, and building information modeling (BIM) data generation system 130.

Computing system 101 executes machine learning system 102, which may be implemented as software, but may in some examples include any combination of hardware, firmware, and software. Machine learning system 102 trains machine learning model 103 having, in this example, image processing model 106 and one or building information modeling (BIM) data models 122A-122N (collectively, “BIM data models 122”). Each of image processing model 106 and BIM data models 122 may represent a different machine learning model, which combine to form overall machine learning model 103 implemented by machine learning system 102.

Computing system 101 may be implemented as any suitable computing system, such as one or more server computers, workstations, laptops, mainframes, appliances, cloud computing systems, smart phones, tablet computers, and/or other computing systems that may be capable of performing operations and/or functions described in accordance with one or more aspects of the present disclosure. In some examples, computing system 101 may represent a cloud computing system, server farm, and/or server cluster (or portion thereof) that provides services to client devices and other devices or systems. In other examples, computing system 101 may represent or be implemented through one or more virtualized compute instances (e.g., virtual machines, containers, etc.) of a data center, cloud computing system, server farm, and/or server cluster.

User device 108 may be operated by a user. User device 108 may be implemented as any suitable client computing system, such as a mobile, non-mobile, wearable, and/or non-wearable computing device. User device 108 may represent a smart phone, a tablet computer, a computerized watch, a personal digital assistant, a virtual assistant, a gaming system, a media player, an e-book reader, a television or television platform, a laptop or notebook computer, a desktop computer, a camera, or any other type of wearable, non-wearable, mobile, or non-mobile computing device that may perform operations in accordance with one or more aspects of the present disclosure.

A user, such as an architect or designer, may interact with BIM data generation system 130 to design buildings. BIM data generation system 130 may receive input data, such as building parameters 124 or user inputs, that parameterizes aspects of a building design and may use the input data to generate BIM data 132. BIM data 132 may include descriptive data for structural features of the buildings, such as building dimensions, the number of floors, window locations and dimensions, floor height, and so forth; floor plans; interiors and exterior structural information; 2D/3D models of buildings or aspects thereof; engineering, electrical, plumbing, lighting, or landscaping data for buildings; etc. BIM data generation system 130 may including computer-aided design (CAD) software to aid in the creation, modification, analysis, or optimization of a building design.

Whereas building parameters 124 for a new building may be generated specifically to be processed by BIM data generation system 130, BIM data generation system 130 may be cross-platform, i.e., interchangeable among and comprehensible to many different design systems. BIM data generation system 130 may be a proprietary system with a specific set of input parameters. Building parameters 124 for a new building may be generated to conform to the set of input parameters for BIM data generation system 130.

BIM data generation system 130 may be implemented as any suitable computing system, such as one or more server computers, workstations, laptops, mainframes, appliances, cloud computing systems, smart phones, tablet computers, and/or other computing systems that may be capable of performing operations and/or functions described in accordance with one or more aspects of the present disclosure. In some examples, BIM data generation system 130 may represent a cloud computing system, server farm, and/or server cluster (or portion thereof) that provides services to client devices and other devices or systems. In other examples, BIM data generation system 130 may represent or be implemented through one or more virtualized compute instances (e.g., virtual machines, containers) of a data center, cloud computing system, server farm, and/or server cluster.

Computing system 101 and user device 108 may be the same computing system or different systems connected by a network. BIM data generation system 130 and user device 108 may be the same computing system or different systems connected by a network. Computing system 101, BIM data generation system 130, and user device 108 may be the same computing system or different systems connected by a network. One or more networks connecting any of the systems of system 100 may be the internet or may include, be a part of, and/or represent any public or private communications network or other network. For instance, the network may each be a cellular, Wi-Fi®, ZigBee, Bluetooth® (or other personal area network—PAN), Near-Field Communication (NFC), ultrawideband, satellite, enterprise, service provider, and/or other type of network enabling transfer of data between computing systems, servers, and computing devices. One or more of client devices, server devices, or other devices may transmit and receive data, commands, control signals, and/or other information across the networks using any suitable communication techniques.

In accordance with techniques of this disclosure, machine learning system 102 generates building parameters for a new building from a building image 114 that includes a depiction of an existing building. A user of user device 108 may provide a building image 114 to computing system 101 for processing. Building image 114 may be a photograph of the existing building. However, in some cases, building image 114 may be a synthetic image, a simulated image, a sketch, a wireframe, an image of a 3D model, or other image that depicts a building.

In inference mode, machine learning system 102 may apply a trained machine learning model 103 to building image 114 to predict values of building parameters 124 of the building depicted in building image 114. Building parameters 124 may include descriptive data for structural features of the buildings, such as building dimensions, the number of floors, window locations and dimensions, floor height, and so forth.

Machine learning model 103 may include one or more neural network models, each made up of a neural network having one or more parameterized layers. Example neural networks can include a convolutional neural network (CNN), a deep neural network (DNN), a recurrent (or “recursive”) neural network (RNN), or a combination thereof. An RNN may be based on a Long Short-Term Memory cell. Other types of machine learning models may be used.

In examples in which the machine learning model 103 includes layers, each of the layers may include a different set of artificial neurons. The layers can include an input layer, an output layer, and one or more hidden layers (which may also be referred to as intermediate layers). The layers may include fully connected layers, convolutional layers, pooling layers, and/or other types of layers. In a fully connected (or “dense”) layer, the output of each neuron of a previous layer forms an input of each neuron of the fully connected layer. In a convolutional layer, each neuron of the convolutional layer processes input from neurons associated with the neuron's receptive field. Pooling layers combine the outputs of neuron clusters at one layer into a single neuron in the next layer. Each input of each artificial neuron in each of the layers may be associated with a corresponding weight, and artificial neurons may each apply an activation function known in the art, such as Rectified Linear Unit (ReLU), Tan H, Sigmoid, etc.

As noted above, in the example of FIG. 1, machine learning model 103 includes multiple sub-models, i.e., image processing model 106 and one or more BIM data models 122, that combine to predict building parameters 124 from building image 114. Image processing model 106 may include a CNN or other neural network trained to perform image processing operations on building image 114. Image processing operations may include transforming building image 114 to, e.g., translate, rotate, deskew, keystone-correct (keystoning), or scale the building depicted in building image 114. Image processing operations may also include detecting a one or more façades, i.e., exterior faces, of the building and may further include identifying the primary façade from among the one or more detected façade. The primary façade is typically the principal front of a building that includes the front entrance, faces the primary street or other public way, or presents as more significant from an architectural standpoint. The transforming operations may include generating an image of a façade of the building from a perspective that is on a line centered within and perpendicular to the façade. In some cases, the transforming operations may include transforming an orientation of the image of the building to generate a frontal view of the building, which may be an example of the generated image of the façade described earlier. Image processing model 106 may output a transformed building image 116 as a predicted view for the building, as shown in FIG. 1.

Image processing operations may also include identifying a building type of the building depicted in building image 114. Building types may include categories of buildings, such as architectural styles or purposes of buildings. Example architectural styles include modern, Gothic, brutalist, Art Deco, neoclassical, ranch, craftsman, etc. Example building purposes include auditorium, apartment, single-family house, gym, house of worship, office building, etc. A building image may have one or more building types. For example, a building image may depict an apartment complex with a modern architectural style.

The image processing model 106 may output a prediction for the building type of the building depicted in building image 114 as building type 115. In some instances, machine learning system 102 may receive the building type of the building depicted in building image 114 in association with building image 114. A user may interact with user device 108 to provide user input indicating the building type to associate with building image 114. Computing system 101 may obtain building image 114 or building type 115 from a storage device or from user device 108 via a network, for instance.

Machine learning system 102 applies one of the one or more BIM data models 122 to a building image to generate and output building parameters 124 of the building depicted in the building image. That is, the one or more BIM data models 122 generate values for certain building parameters of the building, which are output by machine learning system 102. Building parameters 124 may be output as BIM data or used to generate BIM data to parameterize a new building. For example, building parameters 124 may be manually or automatically input to BIM data generation system 130, which may generate an BIM data 132 for a new building that conforms to building parameters 124. Effectively, building parameters 124, automatically generated from a building image, parameterize BIM data 132 for the new building. BIM data 132 may be a 3D model, a wireframe model, a 2D model, a new building image, or other type of model. BIM data 132 may in some cases only be a partial model of a new building. In this way, a user or computing system may use the predicted building parameters 124 to, for instance, replicate the exterior façade or the architectural style of the building in building image 114 in a BIM data 132. Other types of BIM data are described elsewhere in this disclosure.

In various examples, the building image to which one of BIM data models 122 is applied may be the received building image 114 or may be the transformed building image 116.

In some examples, BIM data models 122 are trained to predict building parameters 124 according to a particular building type or combination of building types. For example, BIM data model 122A may predict building parameters 124 for a modern building, BIM data model 122B may predict building parameters 124 for an Art Deco building, BIM data model 122C may predict building parameters 124 for an apartment complex with a modern architectural style (i.e., multiple building types), and so forth. In such examples, after applying image processing model 106, machine learning system 102 selects the BIM data model 122 that corresponds to the one or more building types of the building depicted in building image 114. Again, the building types may be predicted by image processing model 106 or received by machine learning system 102 in association with building image 114. Continuing the above example, machine learning system 102 may select BIM data model 122C for application to a building image that is an apartment complex with a modern architectural style. Machine learning system 102 applies the selected one of the BIM data models 122 to the building image to generate and output building parameters 124 of the building depicted in the building image. Again, the building image to which the BIM data model is applied may be the received building image 114 or a transformed building image 116.

Machine learning system 102 may train machine learning model 103 with training data 104. Training data 104 may include images of buildings and corresponding known descriptive data for the buildings for one or more building parameters, such as building dimensions, number of floors, window locations and dimensions, floor height, interior layouts, and others. The images of buildings may be photographs, synthetic images, sketches, simulated images, wireframes of building, images of 3D models, or other images that depict buildings. Training data 104 may include data describing surface finishing materials and interior and/or exterior architectural elements, such as walls, balconies, stairs, fittings, etc. Training data 104 may include data describing any structure that is not included in the building image but can be derived from the building image.

The machine learning may be supervised learning, semi-supervised learning, weakly supervised learning, or unsupervised learning. In semi-supervised learning, data set includes labeled data and unlabeled data. The AI model is trained on a part of data (labeled data). The AI model then predicts results on the unlabeled data. Of the predicted results, ones having sufficient certainty will be associated with the corresponding data as labeled. This process will be repeated until all the data are labeled. Finally, supervised learning is performed using the resulting data. In weakly supervised learning, an application provides feedbacks for the predicted results as accurate or inaccurate. The learning is performed with cycles of predictions and feedbacks. In unsupervised learning, representative vectors or prototypes are obtained by a clustering method, such as k-means. Building parameters may be set for representative vectors. In accordance with techniques of this disclosure, when a new building image 114 is input, machine learning system 102 may apply machine learning model 103 to identify a closest prototype and compute the corresponding building parameters.

A set of building parameters associated with a building image in training data 104 may be provided in a data structure, such as in a set of key-value pairs, a list, a table, or other associative data structure that can associate a building parameter (e.g., “number of floors”) with a value (e.g., “3”). Machine learning model 103 having been trained with training data 104, machine learning system 102 may apply machine learning model 103 to predict the values for building parameters 124 from building image 114.

In some examples, at least some of building images in training data 104 may be labeled with one or more building types for the corresponding building in the images. Accordingly, image processing model 106 may be trained to predict one or more building types for a building depicted in an input building image 114 during inference mode. In such examples, machine learning system 102 may train only the corresponding one of BIM data models 122 for the one or more building types. Machine learning system 102 may train any of BIM data models 122 for a particular building type by training the BIM data model for the building type on training data 104 that is specific to that building type. Continuing the example from above, for a building image in training data 104 labeled “apartment complex” and “modern architectural style,” machine learning system 102 may train BIM data model 122C that is “trained on” that particular combination of building types. Regarding the input building image 114, visual semantic embeddings can be used to embed labels for building types (image features) into feature spaces. In this case, building parameters are predicted by applying, to each feature space, a closest one of BIM data models 122 for the corresponding building type.

In some examples, at least some of the building images in training data 104 are synthetic images. A program, such as may be implemented by BIM data generation system 130, may accept a set of inputs that includes respective values for a set of building parameters for a building. The program may then generate a synthetic image of a building that conforms to the values for the set of building parameters. Training data 104 may include the generated synthetic image in association with the values for the set of building parameters. A user or another program may modify the input values within a range for multiple dimensions that are the building parameters and input various sets of values for the set of building parameters to generate multiple synthetic images of buildings, and each such generated synthetic image in association with the values for the set of building parameters used to generate the synthetic image may become a portion of training data 104.

As a simple example, building parameters may include two dimensions: (number of floors [1:3], floor height [15 ft.:18 ft.]), where the number of possible floors is in the range [1:3] and the floor height can be either 15 ft. or 18 ft. By manipulating the values for possible combinations of (number of floors, floor height), training data 104 may include six different synthetic images each in association with the values for the building parameters used to generate the synthetic image: (1, 15 ft.), (2, 15 ft.), (3, 15 ft.), (1, 18 ft.), (2, 18 ft.), (3, 18 ft.). Building parameters may include one or more types of building, the values for which may become labels for the corresponding generated synthetic images. Regarding the parameter floor height [15 ft.:18 ft.] in the above example, the two elements do not necessarily indicate possible values for the floor height. The two elements can indicate a range, i.e., the minimum and the maximum of the possible floor height. Thus, the parameter “floor height [15 ft.:18 ft.]” can include any floor height between 15 ft. and 18 ft. inclusive.

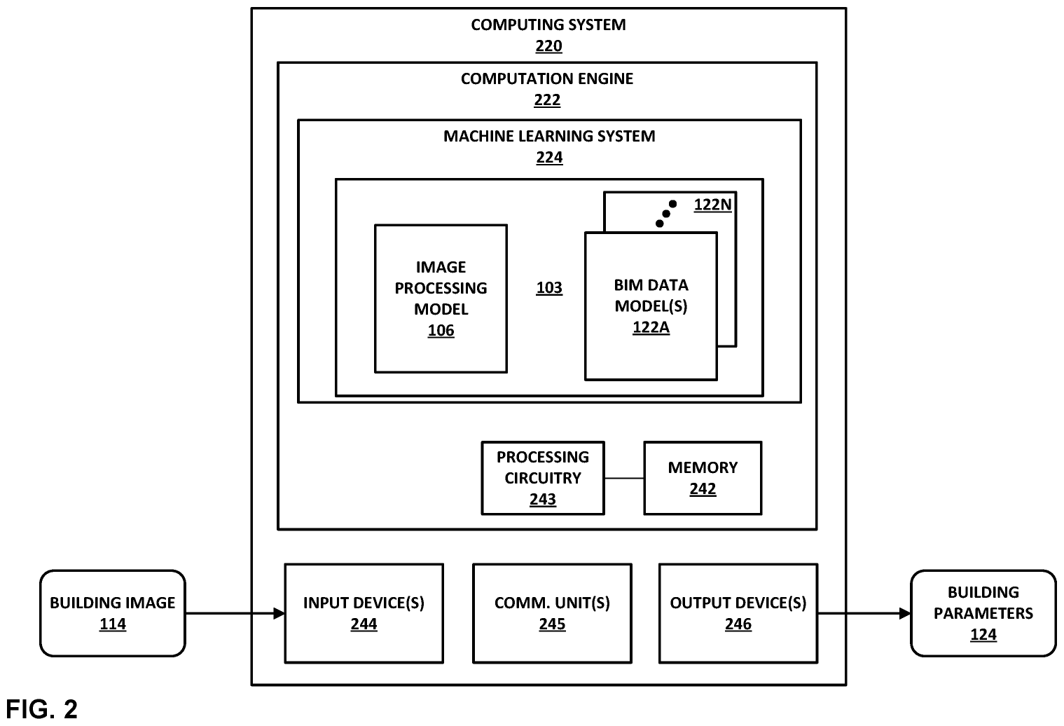

FIG. 2 is an example of a computing system, according to techniques of this disclosure. Computing system 220 represents one or more computing devices configured for executing a machine learning system 224, which may represent an example instance of any machine learning system described in this disclosure, such as machine learning system 102 of FIG. 1.

Memory 242 may store information for processing during operation of computation engine 222. In some examples, memory 242 may include temporary memories, meaning that a primary purpose of the one or more storage devices is not long-term storage. Memory 242 may be configured for short-term storage of information as volatile memory and therefore not retain stored contents if deactivated. Examples of volatile memories include random access memories (RAM), dynamic random access memories (DRAM), static random access memories (SRAM), and other forms of volatile memories known in the art. Memory 242, in some examples, also include one or more computer-readable storage media. Memory 242 may be configured to store larger amounts of information than volatile memory. Memory 242 may further be configured for long-term storage of information as non-volatile memory space and retain information after activate/off cycles. Examples of non-volatile memories include magnetic hard disks, optical discs, floppy disks, Flash memories, or forms of electrically programmable memories (EPROM) or electrically erasable and programmable (EEPROM) memories. Memory 242 may store program instructions and/or data associated with one or more of the modules described in accordance with one or more aspects of this disclosure. Memory 242 may store weights for parameters for machine learning model 103, which in this example include image processing model 106 and BIM data models 122.

Processing circuitry 243 and memory 242 may provide an operating environment or platform for computation engine 222, which may be implemented as software, but may in some examples include any combination of hardware, firmware, and software. Processing circuitry 243 may execute instructions and memory 242 may store instructions and/or data of one or more modules. The combination of processing circuitry 243 and memory 242 may retrieve, store, and/or execute the instructions and/or data of one or more applications, modules, or software. Processing circuitry 243 and memory 242 may also be operably coupled to one or more other software and/or hardware components, including, but not limited to, one or more of the components illustrated in FIG. 2.

Computation engine 222 may perform operations described using software, hardware, firmware, or a mixture of hardware, software, and firmware residing in and/or executing at computing system 220. Computation engine 222 may execute machine learning system 224 or other programs and modules with multiple processors or multiple devices. Computation engine 222 may execute machine learning system 224 or other programs and modules as a virtual machine or container executing on underlying hardware. One or more of such modules may execute as one or more services of an operating system or computing platform. One or more of such modules may execute as one or more executable programs at an application layer of a computing platform.

One or more input devices 244 of computing system 220 may generate, receive, or process input. Such input may include input from a keyboard, pointing device, voice responsive system, video camera, biometric detection/response system, button, sensor, mobile device, control pad, microphone, presence-sensitive screen, network, or any other type of device for detecting input from a human or machine.

One or more output devices 246 may generate, transmit, or process output. Examples of output are tactile, audio, visual, and/or video output. Output devices 246 may include a display, sound card, video graphics adapter card, speaker, presence-sensitive screen, one or more USB interfaces, video and/or audio output interfaces, or any other type of device capable of generating tactile, audio, video, or other output. Output devices 246 may include a display device, which may function as an output device using technologies including liquid crystal displays (LCD), quantum dot display, dot matrix displays, light emitting diode (LED) displays, organic light-emitting diode (OLED) displays, cathode ray tube (CRT) displays, e-ink, or monochrome, color, or any other type of display capable of generating tactile, audio, and/or visual output. In some examples, computing system 220 may include a presence-sensitive display that may serve as a user interface device that operates both as one or more input devices 244 and one or more output devices 246.

One or more communication units 245 of computing system 220 may communicate with devices external to computing system 220 (or among separate computing devices of computing system 220) by transmitting and/or receiving data, and may operate, in some aspects, as both an input device and an output device. In some examples, communication units 245 may communicate with other devices over a network. In other examples, communication units 245 may send and/or receive radio signals on a radio network such as a cellular radio network. Examples of communication units 245 include a network interface card (e.g. such as an Ethernet card), an optical transceiver, a radio frequency transceiver, a GPS receiver, or any other type of device that can send and/or receive information. Other examples of communication units 245 may include Bluetooth®, GPS, 3G, 4G, and Wi-Fi® radios found in mobile devices as well as Universal Serial Bus (USB) controllers and the like.

Input devices 244 or communication units 245 receives building image 114. Machine learning model 103 may be used to generate predicted outputs. Computation engine 222 executes and applies machine learning system 224 to building image 114 to generate predicted outputs in the form of building parameters 124. Output devices 246 or communication units 245 outputs building parameters 124, which may be used for designing a new building. In some examples, input devices 244 may include an image capture device, such as a camera, to generate a building image 114 as a photograph of a building. Machine learning system 224 executed by computing system 220 receives building image 114 in such examples from an integrated or separate image capture device.

Although described as being implemented using neural networks in the example of FIG. 2, machine learning system 224 may also or alternatively apply other types of machine learning to train one or more models. For example, machine learning system 224 may apply one or more of nearest neighbor, naïve Bayes, decision trees, linear regression, support vector machines, neural networks, k-Means clustering, Q-learning, temporal difference, deep adversarial networks, or other supervised, unsupervised, semi-supervised, or reinforcement learning algorithms to train one or more models for prediction.

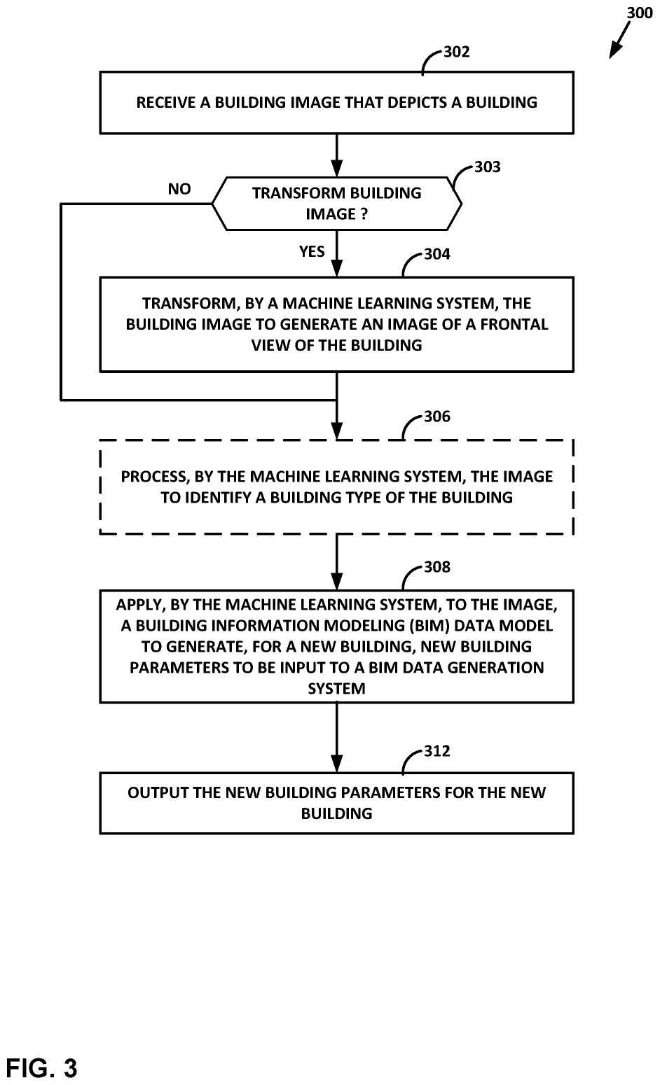

FIG. 3 is a flowchart illustrating an example mode of operation for a machine learning system, according to techniques described in this disclosure. Although described with respect to computing system 220 of FIG. 2 having a computation engine 222 that executes machine learning system 224, mode of operation 300 may be performed by a computation system with respect to other examples of machine learning systems described herein.

In mode of operation 300, computation engine 222 executes machine learning system 102. Machine learning system 102 receives a building image 114, which depicts a building (302). Machine learning system 102 optionally (YES branch of 303) transforms building image 114 to generate an image of frontal view of the depicted building to form building image 116 (304). Building image 114 and building image 116 are referenced below in the description of mode of operation 300 as “the image”.

Machine learning system 102 next optionally processes the image to identify a building type of the building (306). Box 306 is shown in dashed lines to indicate this operation is optional. Machine learning system 102 next selects and applies, to the image (114 or 116), a BIM data model 122 to generate, for a new building, new building parameters to be input to a BIM data generation system (308). In step 308, if the building type is identified, machine learning system 102 may apply the one of BIM data models 122 that has been trained on building images for buildings that conform to the identified building type.

Machine learning system then outputs the new building parameters for the new building (312).

The techniques described in this disclosure may be implemented, at least in part, in hardware, software, firmware or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components or integrated within common or separate hardware or software components.

The techniques described in this disclosure may also be embodied or encoded in a computer-readable medium, such as a computer-readable storage medium, containing instructions. Instructions embedded or encoded in a computer-readable storage medium may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

What is claimed is:

1. A machine learning system for predicting building parameters for an image of a building, the machine learning system comprising:
an input device configured to receive an input comprising an image of a building;
processing circuitry and memory for executing a machine learning system,
wherein the machine learning system is configured to apply a machine learning model, trained using images of buildings and corresponding building parameters for the buildings, to the received image of the building to generate, for a new building, new building parameters to be input to a building information modeling (BIM) data generation system; and
an output device configured to output the new building parameters for the new building.

2. The machine learning system of claim 1,
wherein the machine learning model comprises an image processing model and a BIM data model, and
wherein to apply the machine learning model to the received image of the building, the machine learning system is configured to:
apply the image processing model to the received image to generate an image of a frontal view of the building; and
apply the BIM data model to the generated image of the frontal view of the building to generate the new building parameters for the new building.

3. The machine learning system of claim 2,
wherein the image processing model is trained to transform an orientation of the received image of the building to generate the image of the frontal view of the building.

4. The machine learning system of claim 2,
wherein the BIM data model comprises a plurality of BIM data models for respective building types, and
wherein to apply the machine learning model to the received image of the building the machine learning system is configured to:
apply the image processing model to the generated image of the frontal view of the building to identify a building type of the building; and
apply the corresponding BIM data model, of the plurality of BIM data models, for the identified building type to the generated image of the frontal view to generate the new building parameters, wherein the new building parameters are for a building having the identified building type.

5. The machine learning system of claim 1,
wherein the machine learning model comprises a plurality of BIM data models for respective building types, and
wherein to apply the machine learning model to the received image of the building the machine learning system is configured to:
apply the machine learning model to the received image of the building to identify a building type of the building; and
apply the corresponding BIM data model, of the plurality of BIM data models, for the identified building type to the received image to generate the new building parameters, wherein the new building parameters are for a building having the identified building type.

6. The machine learning system of claim 1,
wherein the machine learning system is further configured to receive a building type of the building,
wherein the machine learning model comprises a plurality of BIM data models for respective building types, and
wherein to apply the machine learning model to the received image of the building the machine learning system is configured to apply the corresponding BIM data model, of the plurality of BIM data models, for the building type of the building, to the received image to generate the new building parameters, wherein the new building parameters are for a building having the building type of the building.

7. The machine learning system of claim 1,
wherein the machine learning system is configured to process the images of buildings and corresponding building parameters for the buildings to train the machine learning model.

8. The machine learning system of claim 7,
wherein the images of the buildings are synthetic images of buildings, and
wherein each of the synthetic images of buildings is generated by inputting, to a program, different values for each of the building parameters to cause the program to generate a synthetic image of a building for each combination of the building parameter values.

9. The machine learning system of claim 7,
wherein the machine learning model comprises plurality of BIM data models for respective building types,
wherein each image of the images of buildings has a label identifying a type of the building, and
wherein to process the images of buildings and corresponding building parameters for the buildings to train the machine learning model, the machine learning system is configured to, for each image of the images of buildings:
select the BIM data model of the plurality of BIM data models that corresponds to the label identifying the type of the building; and
process the image and the corresponding building parameters for the building to train the selected BIM data model.

10. A method comprising:
receiving an image of a building;
applying, by a machine learning system, a machine learning model to the received image of a building to generate, for a new building, new building parameters to be input to a building information modeling (BIM) data generation system,
wherein the machine learning model is trained using images of buildings and corresponding building parameters for the buildings; and
outputting, by the machine learning system, the new building parameters for the new building.

11. The method of claim 10,
wherein the machine learning model comprises an image processing model and a BIM data model, and
wherein applying the machine learning model to the received image of the building to generate the BIM data for the new building comprises:
applying, by the machine learning system, the image processing model to the received image to generate an image of a frontal view of the building; and
applying the BIM data model to the generated image of the frontal view of the building to generate the new building parameters for the new building.

12. The method of claim 11,
wherein the image processing model is trained to transform an orientation of the received image of the building to generate the image of the frontal view of the building.

13. The method of claim 11,
wherein the BIM data model comprises a plurality of BIM data models for respective building types, and
wherein applying the machine learning model to the received image of the building to generate the BIM data for the new building comprises:
applying the image processing model to the generated image of the frontal view of the building to identify a building type of the building; and
applying the corresponding BIM data model, of the plurality of BIM data models, for the identified building type to the generated image of the frontal view to generate the new building parameters, wherein the new building parameters are is for a building having the identified building type.

14. The method of claim 10,
wherein the machine learning model comprises a plurality of BIM data models for respective building types, and
wherein applying the machine learning model to the received image of the building to generate the BIM data for the new building comprises:
applying the machine learning model to the received image of the building to identify a building type of the building; and
applying the corresponding BIM data model, of the plurality of BIM data models, for the identified building type to the received image to generate the new building parameters, wherein the new building parameters are for a building having the identified building type.

15. The method of claim 10, further comprising:
receiving, by the machine learning system, a building type of the building;
wherein the machine learning model comprises a plurality of BIM data models for respective building types, and
wherein applying the machine learning model to the received image of the building to generate the BIM data for the new building comprises:
applying the corresponding BIM data model, of the plurality of BIM data models, for the building type of the building, to the received image to generate the new building parameters, wherein the new building parameters are for a building having the building type of the building.

16. The method of claim 10, further comprising:
processing, by the machine learning system, the images of buildings and corresponding building parameters for the buildings to train the machine learning model.

17. The method of claim 16,
wherein the images of the buildings are synthetic images of buildings, and
wherein each of the synthetic images of buildings is generated by inputting, to a program, different values for each of the building parameters to generate a synthetic image of a building for each combination of the building parameter values.

18. The method of claim 16,
wherein the machine learning model comprises plurality of BIM data models for respective building types,
wherein each image of the images of buildings has a label identifying a type of the building, and
wherein the processing comprises, for each image of the images of buildings:
selecting, by the machine learning system, the BIM data model of the plurality of BIM data models that corresponds to the label identifying the type of the building; and
processing, by the machine learning system, the image and the corresponding building parameters for the building to train the selected BIM data model.

19. The method of claim 10, further comprising:
generating, by the BIM data generation system, using the new building parameters for the new building, BIM data for the new building.

20. The method of claim 10, wherein the new building parameters comprise one or more of a building dimension, a number of floors, a floor height, a location of a window, or a dimension of a window.

21. A non-transitory computer-readable medium comprising machine readable instructions for causing processing circuitry to perform operations comprising:
receiving an image of a building;
applying a machine learning model to the received image of a building to generate, for a new building, new building parameters to be input to a building information modeling (BIM) data generation system,
wherein the machine learning model is trained using images of buildings and corresponding building parameters for the buildings; and
outputting the new building parameters for the new building.
